(19) United States
(12) Patent Application Publication
(10) Pub. No.: US 2025/0204014 A1
(43) Pub. Date: Jun. 19, 2025

(54) SEMICONDUCTOR DEVICES WITH REDUCED LEAKAGE CURRENT AND METHODS OF FORMING THE SAME

(71) Applicant: Taiwan Semiconductor Manufacturing Company, Ltd., Hsin-Chu (TW)

(72) Inventors: Shih-Hao Lin, Hsinchu (TW); Chih-Hsiang Huang, Hsinchu County (TW)

(21) Appl. No.: 18/628,720

(22) Filed: Apr. 6, 2024

Related U.S. Application Data
(60) Provisional application No. 63/611,812, filed on Dec. 19, 2023.

(51) Int. Cl. H01L 29/49; H01L 21/28; H01L 29/06; H01L 29/775; H01L 29/786

(52) U.S. Cl. CPC H10D 64/667; H01L 21/28088; H10D 30/43; H10D 30/6757; H10D 62/121

(57) ABSTRACT

Semiconductor structures and methods are provided. An exemplary method according to the present disclosure includes forming a dielectric layer over a portion of a substrate, forming an aluminum-containing work function layer over the dielectric layer, where a concentration of aluminum in a first portion of the aluminum-containing work function layer is different than the concentration of aluminum in a second portion of the aluminum-containing work function layer, and forming a metal layer over the aluminum-containing work function layer.

### PRIORITY

This application is a non-provisional application of and claims benefit of U.S. Provisional Patent Application Ser. No. 63/611,812, filed Dec. 19, 2023, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs. Integrated circuits include a variety of circuit device components, such as transistors. One characteristic of a transistor is its threshold voltage. As transistor sizes become smaller, it is desirable to find ways to reduce the threshold voltage without adversely affecting other aspects of the transistor.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 is a flowchart illustrating a method of forming a semiconductor structure, according to various embodiments of the present disclosure.

FIG. 2 illustrates a fragmentary top view of an exemplary structure to undergo various stages of operations in the method of FIG. 1, according to various aspects of the disclosure.

FIGS. 3A, 4A, 5A, 6A, 7A, 17A, 18A, and 19A illustrates fragmentary cross-sectional views of the structure taken along line A-A′ as shown in FIG. 2 during various fabrication stages in the method of FIG. 1, according to various aspects of the disclosure.

FIGS. 3B, 4B, 5B, 6B, 7B, 17B, 18B, and 19B illustrate fragmentary cross-sectional views of the structure taken along line B-B′ as shown in FIG. 2 during various fabrication stages in the method of FIG. 1, according to various aspects of the disclosure.

FIGS. 8, 9, 11, 12, 14, and 15 illustrate enlarged views of a portion of the structure shown in FIG. 7 during various fabrication stages in the method of FIG. 1, according to various embodiments of the disclosure.

FIGS. 10, 13, and 16 illustrate graphs corresponding to exemplary ratio profiles for the portion of the structure in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

A functional gate stack of a transistor includes a gate electrode over a gate dielectric layer. The gate electrode may include a work function layer formed of a conductive layer of metal or metal alloy with proper work function such that the corresponding transistor is enhanced for its device performance (for example, reduced threshold voltage). As described above, it is desirable to find ways to reduce the threshold voltage without adversely affecting other aspects of the transistor. One way to reduce the threshold voltage is to increase the thickness of the work function metal layer that is part of the gate stack of the transistor. However, increasing the thickness of the work function metal layer becomes more difficult when producing smaller circuits. For embodiments in which the transistor is an N-type transistor and the work function layer includes an aluminum-containing metal alloy layer, another way to reduce the threshold voltage is to increase the concentration (e.g., atomic percentage) of aluminum in the aluminum-containing metal alloy layer. However, increasing the concentration of aluminum may cause more aluminum atoms to diffuse into the gate dielectric layer, thereby leading to an increased gate leakage current. The aluminum atoms may also diffuse into channel regions (e.g., nanostructures) of the transistor, leading to carrier mobility degradation.

The present disclosure relates to transistors with reduced threshold voltages and reduced gate leakage current and methods of forming the same. An N-type transistor according to embodiments of the present disclosure includes a gate dielectric layer and a gate electrode over the gate dielectric layer. The work function layer of the gate electrode includes a metal alloy layer containing aluminum. In an embodiment, a concentration of aluminum in the work function layer is not uniform and increases along a thickness of the work function layer from its bottom surface to its top surface. In some embodiments, the work function layer includes titanium aluminum (TiAl), and a ratio of the concentration of the aluminum in the TiAl-based work function layer to a concentration of the titanium in the TiAl-based work function layer has a gradient profile. An upper portion of the TiAl-based work function layer with a higher aluminum concentration can contribute to the modulation of the threshold voltage and the reduction of the deposition thickness of the TiAl-based work function layer. A lower portion of the TiAl-based work function layer with a lower aluminum concentration can contribute to the reduction of the aluminum diffusion and improvement of the gate leakage current and carrier mobility.

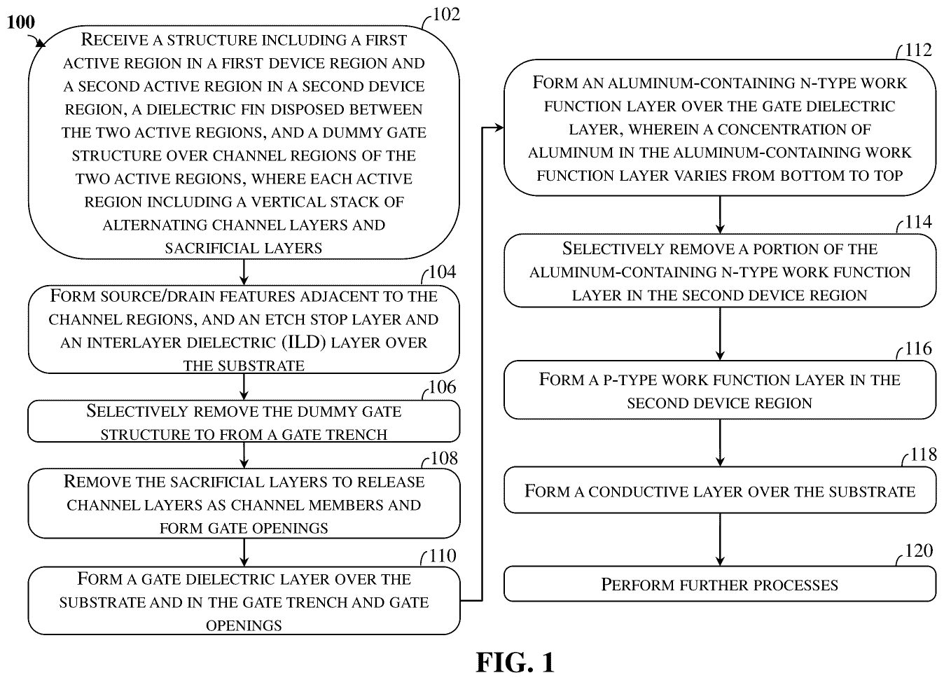

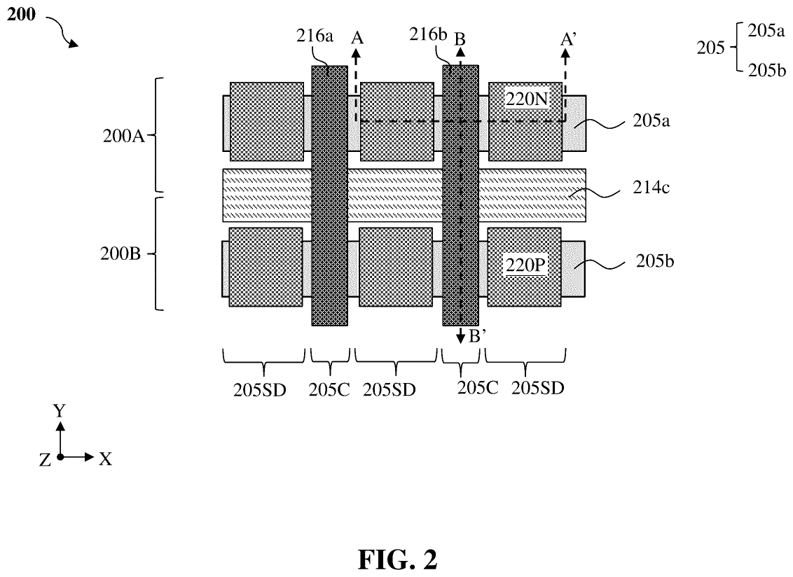

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2-19B, which are fragmentary cross-sectional views or top views of a structure 200 at different stages of fabrication according to embodiments of method 100 or graphs corresponding to exemplary ratio profiles for a portion of the structure. Method 100 is merely an example and is not intended to limit the present disclosure to what is explicitly illustrated therein. Additional steps may be provided before, during and after the method 100, and some steps described can be replaced, eliminated, or moved around for additional embodiments of the method. Not all steps are described herein in detail for reasons of simplicity. Because the structure 200 will be fabricated into a semiconductor structure 200 upon conclusion of the fabrication processes, the structure 200 may be referred to as the semiconductor structure 200 as the context requires. For avoidance of doubts, the X, Y and Z directions in the figures are perpendicular to one another and are used consistently. Throughout the present disclosure, like reference numerals denote like features unless otherwise excepted.

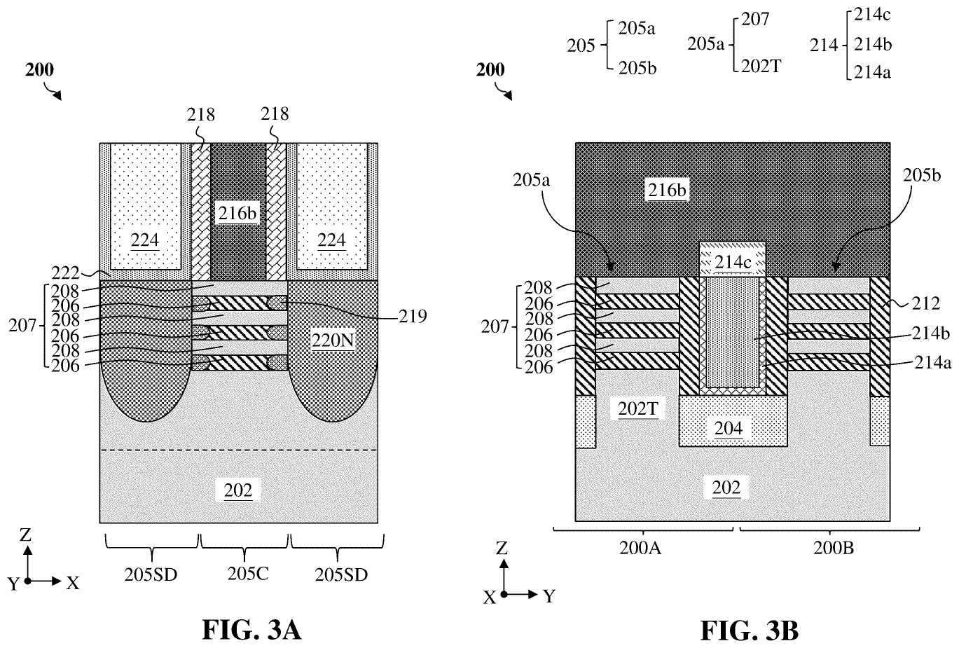

Referring to FIGS. 1, 2, and 3A-3B, method 100 includes a block 102 where a structure 200 is received. FIG. 3A depicts a fragmentary cross-sectional view of the structure 200 taken along line A-A shown in FIG. 2, and FIG. 3B depicts a fragmentary cross-sectional view of the structure 200 taken along line B-B shown in FIG. 2. In this illustrated embodiment, the structure 200 includes a first device region 200A for forming N-type devices (e.g., N-type gate-all-around (GAA) transistors) and a second device region 200B for forming P-type devices (e.g., P-type GAA transistors). The structure 200 includes a substrate 202 (shown in FIGS. 3A-3B). In an embodiment, the substrate 202 is a bulk silicon substrate (i.e., including bulk single-crystalline silicon). The substrate 202 may include other semiconductor materials in various embodiment, such as germanium, silicon carbide, gallium arsenide, gallium phosphide, indium phosphide, indium arsenide, indium antimonide, SiGe, GaAsP, AlInAs, AlGaAs, GaInAs, GaInP, GaInAsP, or combinations thereof. In some alternative embodiments, the substrate 202 may be a semiconductor-on-insulator substrate, such as a silicon-on-insulator (SOI) substrate, a silicon germanium-on-insulator substrate, or a germanium-on-insulator substrate, and includes a carrier, an insulator on the carrier, and a semiconductor layer on the insulator. The substrate 202 can include various doped regions configured according to design requirements of semiconductor structure 200. P-type doped regions may include p-type dopants, such as boron, indium, other p-type dopant, or combinations thereof. N-type doped regions may include n-type dopants, such as phosphorus, arsenic, other n-type dopant, or combinations thereof. In some implementations, the substrate 202 includes doped regions formed with a combination of p-type dopants and n-type dopants. The various doped regions can be formed directly on and/or in substrate 202, for example, providing a p-well structure, an n-well structure, a dual-well structure, a raised structure, or combinations thereof. An ion implantation process, a diffusion process, and/or other suitable doping process can be performed to form the various doped regions.

The structure 200 also includes multiple fin-shaped active regions (e.g., fin-shaped active regions 205a, 205b) disposed over the substrate 202. In the present embodiments, the fin-shaped active region 205a is formed in the first device region 200A (shown in FIG. 2) of the structure 200, and the fin-shaped active region 205b is formed in the second device region 200B of the structure 200. The fin-shaped active regions 205a, 205b may be separately or collectively referred to as a fin-shaped active region 205 or fin-shaped active regions 205. Each of the fin-shaped active regions 205 extends lengthwise along the X direction and is divided into channel regions 205C and source/drain regions 205SD. Source/drain region(s) may refer to a source region or a drain region, individually or collectively dependent upon the context.

The fin-shaped active region 205 may be formed from a top portion 202T of the substrate 202 and a vertical stack 207 (shown in FIGS. 3A-3B) of alternating semiconductor layers 206 and 208 using a combination of lithography and etch steps. In the depicted embodiment, the vertical stack 207 of alternating semiconductor layers 206 and 208 includes a number of channel layers 208 interleaved by a number of sacrificial layers 206. Each channel layer 208 may include a semiconductor material such as, silicon, germanium, silicon carbide, silicon germanium, GeSn, SiGeSn, SiGeCSn, other suitable semiconductor materials, or combinations thereof, while each sacrificial layer 206 has a composition different from that of the channel layer 208. In an embodiment, the channel layer 208 includes silicon (Si), the sacrificial layer 206 includes silicon germanium (SiGe). The channel layers 208 and the sacrificial layers 206 may be epitaxially deposited on the substrate 202 using molecular beam epitaxy (MBE), vapor-phase epitaxy (VPE), ultra-high vacuum CVD (UHV-CVD), and/or other suitable epitaxial growth processes. In some examples, each of the fin-shaped active regions 205 may include a total of three to ten pairs of alternating sacrificial layers 206 and channel layers 208; of course, other configurations may also be applicable depending upon specific design requirements.

The structure 200 also includes an isolation feature 204 (shown in FIG. 3B) formed over the substrate 202 to isolate two adjacent fin-shaped active regions. The isolation feature 204 may also be referred to as a shallow trench isolation (STI) feature. In some embodiments, the STI feature 204 may include silicon oxide, silicon oxynitride, fluorine-doped silicate glass (FSG), a low-k dielectric, combinations thereof, and/or other suitable materials.

Referring to FIGS. 2 and 3B, the structure 200 also includes cladding layers 212 extending along sidewall surfaces of the fin-shaped active regions 205. In some embodiments, the cladding layer 212 may have a composition that is substantially the same as that of the sacrificial layer 206, such that they may be selectively removed by a common etching process. In an embodiment, the cladding layer 212 is formed of SiGe.

Still referring to FIGS. 2 and 3B, the structure 200 also includes a hybrid fin 214 formed over the STI feature 204 and between two adjacent fin-shaped active regions 205. The hybrid fin 214 is spaced apart from the fin-shaped active regions 205 by the cladding layers 212. In some embodiments, the hybrid fin 214 may be a single-layer structure. In some other embodiments, the hybrid fin 214 may include a multi-layer structure. For example, as shown in FIG. 3B, the hybrid fin 214 includes a dielectric layer 214b embedded in a dielectric layer 214a. In other words, the dielectric layer 214a extends along both sidewall and bottom surfaces of the dielectric layer 214b. The dielectric layer 214a may include silicon nitride, silicon carbon nitride (SiCN), silicon oxycarbonitride (SiOCN), or other suitable materials. In an embodiment, the dielectric layer 214a is formed of silicon carbon nitride, the dielectric layer 214b is formed of silicon oxide. The hybrid fin 214 also includes a helmet layer 214c formed over the dielectric layers 214a-214b. The helmet layer 214c may be a high-K dielectric layer and may include silicon nitride, aluminum oxide, aluminum nitride, aluminum oxynitride, zirconium oxide, zirconium nitride, zirconium aluminum oxide, hafnium oxide, other high-K material, or a suitable dielectric material. In some examples, the helmet layer 214c may be configured to divide a gate stack into multiple portions (e.g., 240 and 242) by itself or along with a gate cut feature disposed over the hybrid fin 214.

Still referring to FIGS. 2 and 3A-3B, the structure 200 also includes dummy gate structures 216a and 216b formed over channel regions 205C of the fin-shaped active regions 205. In some embodiments, the dummy gate structures 216a and 216b may share substantially the same composition and dimension. The channel regions 205C and the dummy gate structures 216a and 216b also define source/drain regions 205SD that are not vertically overlapped by the dummy gate structures 216a and 216b. Each of the channel regions 205C is disposed between two source/drain regions 205SD along the X direction. Two dummy gate structures 216a-216b are shown in FIG. 2 but the structure 200 may include other numbers of dummy gate structures. In this embodiment, a gate replacement process (or gate-last process) is adopted where the dummy gate structures 216a and 216b serve as placeholders for functional gate stacks (e.g., functional gate stacks 240 and/or 242). Other processes for forming the functional gate stacks are possible. In the present embodiments, although not separately shown, each of the dummy gate structures 216a and 216b includes a dummy gate dielectric layer (e.g., silicon oxide) and a dummy gate electrode (e.g., polysilicon) disposed over the dummy gate dielectric layer. As discussed in detail below, the dummy gate structures 216a and 216b are configured to be replaced with a respective functional gate stack (e.g., functional gate stack 240).

Still referring to FIG. 3A, the structure 200 also includes gate spacers 218 extending along sidewalls of the dummy gate structures 216a and 216b. In some embodiments, the gate spacers 218 may include silicon oxide, silicon oxycarbide, silicon carbonitride, silicon oxycarbonitride, silicon nitride, zirconium oxide, aluminum oxide, or a suitable dielectric material. The gate spacers 218 may be a single-layer structure or a multi-layer structure. Additionally, the structure 200 also includes inner spacer features 219 disposed between two adjacent channel layers 208 and in direct contact with the sacrificial layers 206 in the channel regions 205C. The inner spacer features 219 may include silicon nitride, silicon oxycarbonitride, silicon carbonitride, silicon oxide, silicon oxycarbide, silicon carbide, silico oxynitride, other suitable materials, or combinations thereof.

Still referring to FIGS. 1, 2, and 3A-3B, method 100 includes a block 104 where source/drain features 220N and 220P are formed adjacent to the channel regions 205C, a contact etch stop layer (CESL) 222 and an interlayer dielectric (ILD) layer 224 are formed over the source/drain features 220N and 220P. The source/drain features 220N and 220P are formed in and/or over source/drain regions 205SD and coupled to the channel layers 208 in the channel regions 205C. In the present embodiments, the source/drain features 220N are N-type source/drain features and are formed in the first device region 200A, and the source/drain features 220P are P-type source/drain features and are formed in the second device region 200B. Exemplary n-type source/drain features may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. Exemplary p-type source/drain features may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process.

Still referring to FIG. 3A, a contact etch stop layer (CESL) 222 and an interlayer dielectric (ILD) layer 224 are formed over the structure 200. The CESL 222 is configured to protect the various underlying components during subsequent fabrication processes and may include silicon nitride, silicon oxynitride, and/or other suitable materials and may be formed by atomic layer deposition (ALD), chemical vapor deposition (CVD), plasma-enhanced chemical vapor deposition (PECVD) process and/or other suitable deposition or oxidation processes. As shown in FIG. 3A, the CESL 222 may be formed on top surfaces of the source/drain features 220 and sidewalls of the gate spacers 218. The ILD layer 224 is deposited by a CVD process, a PECVD process or other suitable deposition technique over the structure 200 after the depositing of the CESL 222. The ILD layer 224 may include silicon oxide, a low-k dielectric material, tetraethyl orthosilicate (TEOS), doped silicon oxide (e.g., BPSG, FSG, PSG, BSG, etc.), other suitable dielectric materials, or combinations thereof. One or more chemical mechanical planarization (CMP) processes may be performed to planarize the top surface of the structure 200 after the depositing of the CESL 222 and the ILD layer 224.

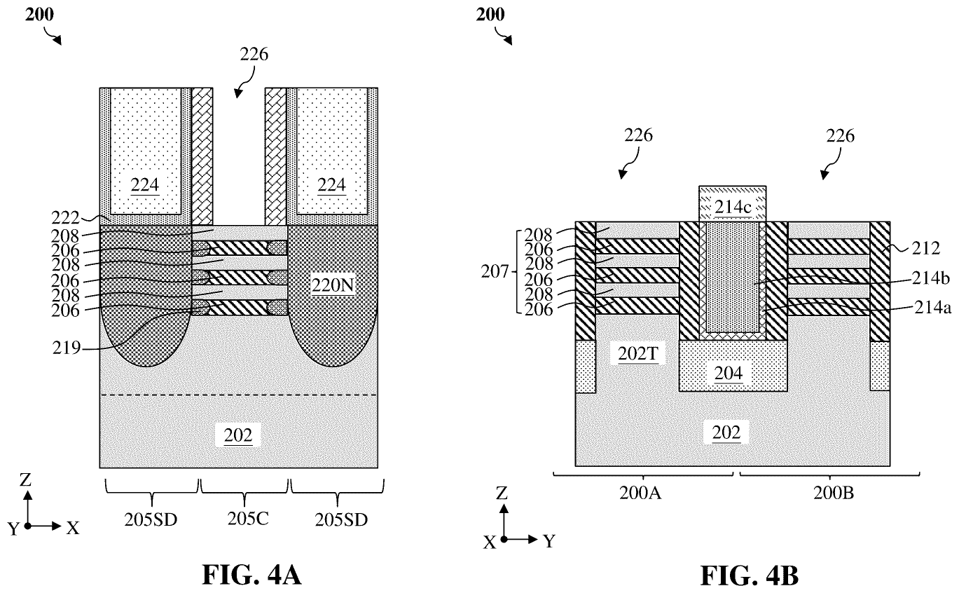

Referring to FIGS. 1 and 4A-4B, method 100 includes a block 106 where the dummy gate structures 216a-216b are selectively removed to form gate trenches 226 over the channel regions 205C. The dummy gate structures 216a-216b are selectively removed by an etching process. The etching process for removing the dummy gate structures 216a-216b may include any suitable process, such as a dry etching process, a wet etching process, or combinations thereof, and is configured to selectively remove the dummy gate structures 216a-216b without substantially etching the channel layers 208, the sacrificial layers 206, the gate spacers 218, the hybrid fin 214, the CESL 222, and the ILD layer 224.

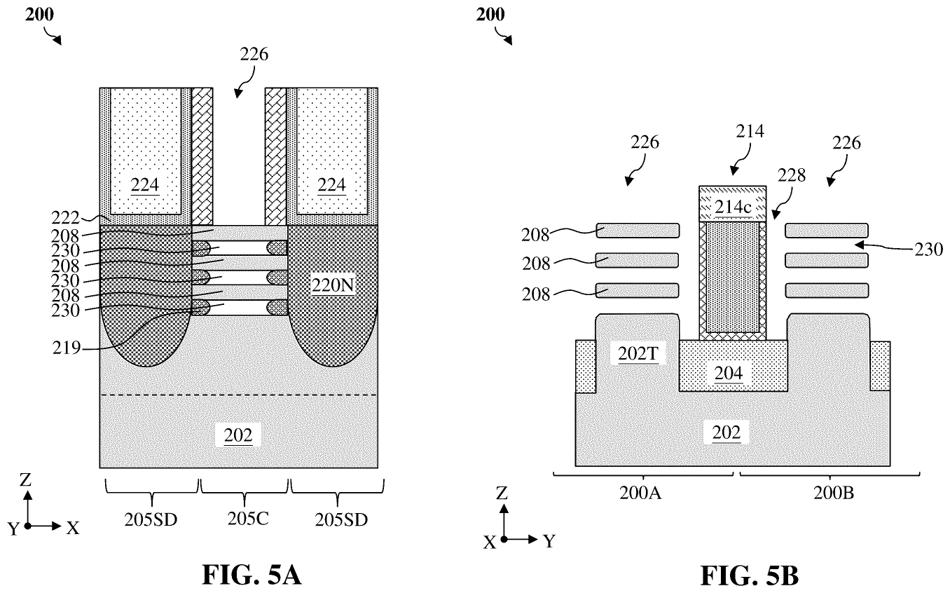

Referring to FIGS. 1 and 5A-5B, method 100 includes a block 108 where the sacrificial layers 206 are selectively removed to release the channel layers 208 as channel members 208. After the selective removal of the dummy gate structures 216a-216b, without substantially removing the channel layers 208, one or more etching processes may be performed to selectively remove the cladding layers 212 and the sacrificial layers 206 to release the channel layers 208 as channel members 208. Since the composition of the cladding layers 212 is the same as the composition of the sacrificial layers 206, the cladding layers 212 may be removed along with the sacrificial layers 206. In one example, the etching process for removing the sacrificial layers 206 and the cladding layers 212 may be a wet etching process that employs an oxidant such as ammonium hydroxide (NH₄OH), ozone (O₃), nitric acid (HNO₃), hydrogen peroxide (H₂O₂), other suitable oxidants, and a fluorine-based etchant such as hydrofluoric acid (HF), ammonium fluoride (NH₄F), other suitable etchants, or combinations thereof. The removal of the cladding layers 212 forms trenches 228 between the stack of channel members 208 and the hybrid fin 214, and the removal of the sacrificial layers 206 forms gate openings 230.

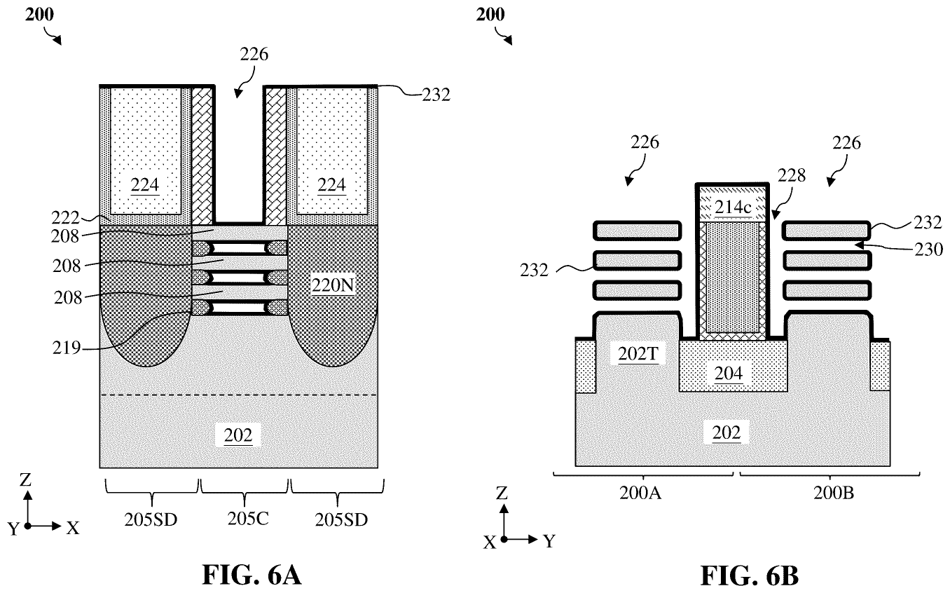

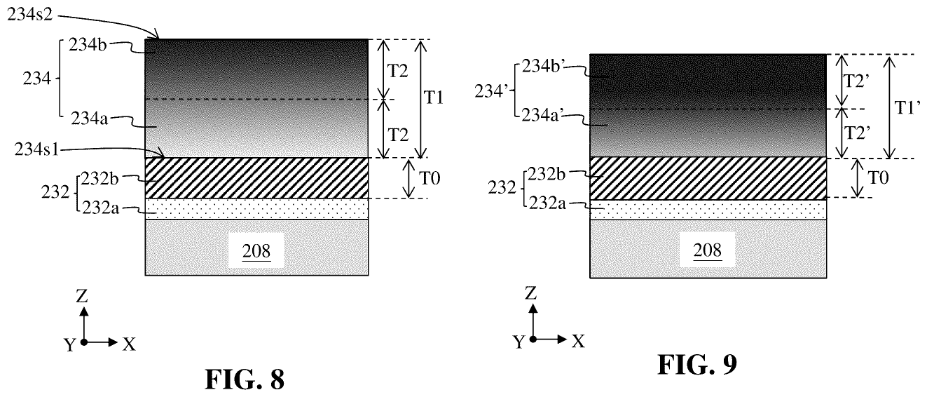

Referring to FIGS. 1 and 6A-6B, method 100 includes a block 110 where a gate dielectric layer 232 is formed over the structure 200. In some embodiments, the gate dielectric layer 232 is a multi-layer structure that includes an interfacial layer 232a (shown in FIG. 8) and a high-K dielectric layer 232b (shown in FIG. 8) over the interfacial layer 232a. In some embodiments, the interfacial layer 232a may be conformally deposited over the substrate 202, including in the gate trenches 226, the trenches 228 and the gate openings 230. In some other implementations, the interfacial layer 232a may include silicon oxide and may be formed by thermal oxidization. The high-K dielectric layer 232b is then conformally deposited over the structure 200 by performing a deposition process (e.g., CVD, ALD) to have a generally uniform thickness T0 (shown in FIG. 8) over the top surface of the structure 200 to partially fill the trenches 226 and 228, and gate openings 230. The term “conformally” may be used herein for ease of description of a layer having substantially uniform thickness over various regions. The high-K dielectric layer 232b may include dielectric materials having a high dielectric constant, for example, greater than a dielectric constant of silicon oxide. Exemplary high-K dielectric materials include hafnium, zirconium, tantalum, titanium, oxygen, nitrogen, other suitable constituent, or combinations thereof. In some implementations, the high-K dielectric layer 232b may include a high-k dielectric material including, for example, HfO₂, HfSiO, HfSiON, HfTaO, HfTiO, HfZrO, ZrO₂, TiO₂, Ta₂O₅, other suitable high-k dielectric material, or combinations thereof.

Referring to FIGS. 1, 7A-7B, 8, 9, and 10, method 100 includes a block 112 where an aluminum-containing N-type work function layer 234 is conformally deposited over the gate dielectric layer 232. In an embodiment, the aluminum-containing N-type work function layer 234 is conformally deposited over the structure 200 to have a generally uniform thickness T1 over the top surface of the structure 200 to partially fill the gate trenches 226, the trenches 228 and the gate openings 230. In some embodiments, the aluminum-containing N-type work function layer 234 may include titanium aluminum (TiAl), titanium aluminum carbide (TiAlC), tantalum aluminum (TaAl), or titanium aluminum nitride (TiAlN), or other suitable materials and may be deposited using atomic layer deposition (ALD).

As described above, aluminum may diffuse around, including upward and downward diffusion. For embodiments in which the N-type work function layer includes aluminum, aluminum in this aluminum-containing N-type work function layer may diffuse into the portion of the gate dielectric layer that is in direct contact with the aluminum-containing N-type work function layer, leading to a contaminated gate dielectric layer, which could aggravate gate leakage current. The aluminum may even diffuse into the channel layers 208, leading to carrier mobility degradation. In the present embodiments, to reduce aluminum diffusion without sacrificing the aluminum-containing N-type work function layer's ability of reducing the threshold voltage Vt of the transistor, a concentration (e.g., atomic percentage) of aluminum in the aluminum-containing N-type work function layer 234 in the present disclosure is not uniform from bottom to top. In some embodiments, the concentration of aluminum in the aluminum-containing N-type work function layer 234 may be a function of the thickness T1 within the aluminum-containing N-type work function layer (e.g., from a bottom surface of the aluminum-containing N-type work function layer towards a top surface of the aluminum-containing N-type work function layer). In an embodiment, a concentration of aluminum in a first portion of the aluminum-containing N-type work function layer 234 that is closer to the gate dielectric layer 232 is lower than a concentration of aluminum in a second portion of the aluminum-containing N-type work function layer 234 that is further away from the gate dielectric layer 232. The concentration of aluminum in the first portion may be substantially uniform or gradient, and the concentration in the second portion of aluminum may be substantially uniform or gradient. The non-uniform concentration of the aluminum in the aluminum-containing N-type work function layer 234 may be achieved by adjusting flow rate ratio of precursors. For example, in embodiments in which the aluminum-containing N-type work function layer 234 is formed of titanium aluminum (TiAl), flow rates of Ti precursor (e.g., TiCl₄) and Al precursor (e.g., trimethylaluminum (TMA)) may be adjusted along with the deposition of the titanium aluminum layer during the ALD process to form the aluminum-containing N-type work function layer 234 with non-uniform concentration of the aluminum. That is, concentrations of aluminum and titanium in the aluminum-containing N-type work function layer 234 may be modulated without introducing additional photomask.

An enlarged view of a portion 200C of the structure 200 is shown in FIG. 8, according to one embodiment of the present disclosure. The aluminum-containing N-type work function layer 234 having the thickness T1 is disposed over and in direct contact with the gate dielectric layer 232. In an embodiment, a ratio of the thickness T1 of the aluminum-containing N-type work function layer 234 to the thickness T0 of the high-K dielectric layer 232b (i.e., T1/T0) is in a range between about 1.5:1 and about 3.5:1. If the ratio of T1 to T0 is greater than 3.5:1, spacing for forming subsequent layers of the gate stack may be too small, leading to an increased parasitic resistance and increased gap fill difficulty. If the ratio of T1 to T0 is less than 1.5:1, the aluminum-containing N-type work function layer 234 may be too thin to contribute to the modulation of the threshold voltage Vt of the transistor.

In this present embodiments, the concentration (e.g., atomic percentage) of aluminum in the aluminum-containing N-type work function layer 234 gradually increases from bottom to top. That is, a concentration (e.g., atomic percentage) of aluminum at a bottom surface 234s1 of the aluminum-containing N-type work function layer 234 is lower than a concentration (e.g., atomic percentage) of aluminum at a top surface 234s2 of the aluminum-containing N-type work function layer 234. In the embodiment represented by FIG. 8, the aluminum-containing N-type work function layer 234 has a first portion 234a and a second portion 234b over the first portion. A first concentration of aluminum in the first portion 234a of the aluminum-containing N-type work function layer 234 that is closer to the gate dielectric layer 232 is lower than a second concentration of aluminum in the second portion 234b of the aluminum-containing N-type work function layer 234 that is further away from the gate dielectric layer 232. The first concentration of aluminum has a gradient profile, and the second concentration of aluminum also has a gradient profile. In other words, a concentration of aluminum at the bottom surface 234s1 is the lowest aluminum concentration in the aluminum-containing N-type work function layer 234, and a concentration of aluminum at the top surface 234s2 is the highest aluminum concentration in the aluminum-containing N-type work function layer 234. In some embodiments, a thickness (e.g., T2) of the first portion 234a of the aluminum-containing N-type work function layer 234 is substantially equal to a thickness T2 of the second portion 234b of the aluminum-containing N-type work function layer 234. That is, each of the first portion 234a and the second portion 234b is a half of the aluminum-containing N-type work function layer 234.

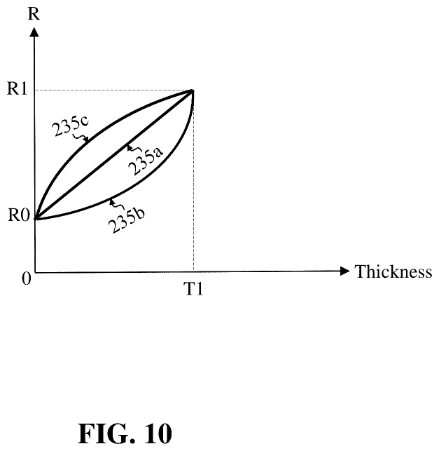

In an embodiment, the aluminum-containing N-type work function layer 234 is formed of titanium aluminum (TiAl), and a ratio (hereinafter referred to as the “ratio R”) of the concentration (e.g., atomic percentage) of aluminum in the aluminum-containing N-type work function layer 234 to a concentration (e.g., atomic percentage) of titanium in the aluminum-containing N-type work function layer 234 has a gradient profile that gradually increases along thickness T1 from the bottom surface 234s1 to the top surface 234s2. The gradient profile of the ratio R may be represented by the line 235a, the curve 235b, or the curve 235c shown in FIG. 10. That is, the ratio may linearly increase or non-linearly increase from a ratio R0 to a ratio R1. R0 stands for the ratio R at the bottom surface 234s1 of the aluminum-containing N-type work function layer 234, and R1 stands for the ratio R at the top surface 234s2 of the aluminum-containing N-type work function layer 234. In an embodiment, the ratio R is in a range between about 0.4 and about 1. If the ratio R is less than 0.4, the aluminum-containing N-type work function layer 234 may not be able to provide enough Vt modulation. If the ratio R is greater than 1, there may be too many aluminum atoms diffusing. In an embodiment, the ratio R is in a range between about 0.4 and about 0.8, and a ratio of the thickness T1 to the thickness T0 is in a range between about 2.5:1 and about 3.5:1. In an embodiment, the ratio R in the first portion 234a may be in a range between about 0.4 and about 0.6, and the ratio R in the second portion 234b may be in a range between about 0.6 and about 0.8. By providing the gradient ratio R profile, the number of aluminum atoms that may diffuse into the gate dielectric layer 232 and the channel layer 208 may be reduced, thereby providing reduced gate leakage current and improved carrier mobility.

In another embodiment represented by FIG. 9, which is an enlarged view of a portion 200C of the structure 200 according to another embodiment of the present disclosure, to alleviate gap fill issue without sacrificing the reduced gate leakage current and improved carrier mobility, the thickness of the aluminum-containing N-type work function layer 234 may be reduced from T1 to T1′. In an embodiment, a ratio of the thickness T1′ to the thickness T0 of the high-K dielectric layer 232b is in a range between about 1:1.5 and about 1:2.5. In some embodiments, a ratio of the thickness T1′ to the thickness T1 is in a range between about 0.7 and about 0.9. Reducing the thickness of the aluminum-containing N-type work function layer 234 may advantageously reduce the difficulty of depositing the aluminum-containing N-type work function layer 234 without generating air gaps and may thus alleviate gap fill issue. In this embodiment, to compensate for the impact to the threshold voltage Vt caused by the reduced thickness of the aluminum-containing N-type work function layer 234, the ratio R of the concentration of aluminum to the concentration of titanium to in the aluminum-containing N-type work function layer 234 may be adjusted. For ease of description, the aluminum-containing N-type work function layer 234 in embodiment represented by FIG. 9 is hereinafter referred to as the aluminum-containing N-type work function layer 234′. In this embodiment, the aluminum-containing N-type work function layer 234′ has a first portion 234a′ and a second portion 234b′. Compared with the aluminum-containing N-type work function layer 234 that has the ratio R in the range between about 0.4 and about 0.8, the ratio R of the aluminum-containing N-type work function layer 234′ may be increased. More specifically, in an embodiment, the ratio R in the aluminum-containing N-type work function layer 234′ is in a range between about 0.5 and about 1. If the ratio R is less than 0.5, the threshold voltage Vt of the device may not be efficiently reduced, leading to a higher power consumption; and if the ratio R is greater than 1, too many aluminum atoms may diffuse into the gate dielectric layer 232 and the channel layers 208, leading to device performance degradation. The ratio R profile of the aluminum-containing N-type work function layer 234′ may be similar in shape to the ratio R profile of the aluminum-containing N-type work function layer 234 represented by FIG. 10, and repeated description may be omitted. In an embodiment, the ratio R in the first portion 234a′ may be in a range between about 0.5 and about 0.75 and is greater than that of the first portion 234a in FIG. 8, and the ratio R in the second portion 234b′ may be in a range between about 0.75 and about 1 and is greater than the ratio R in the first portion 234a′ and the ratio R in the second portion 234b in FIG. 8.

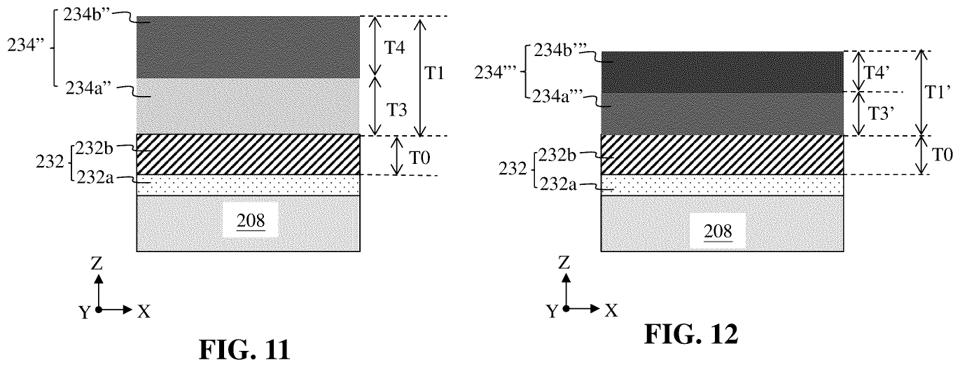

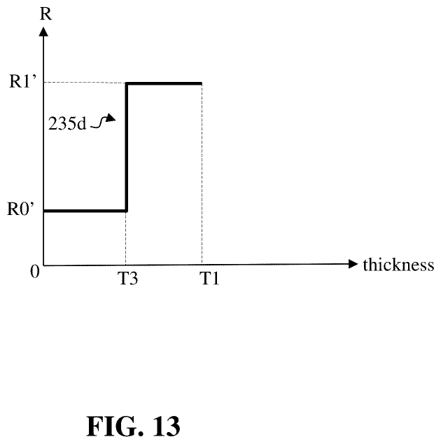

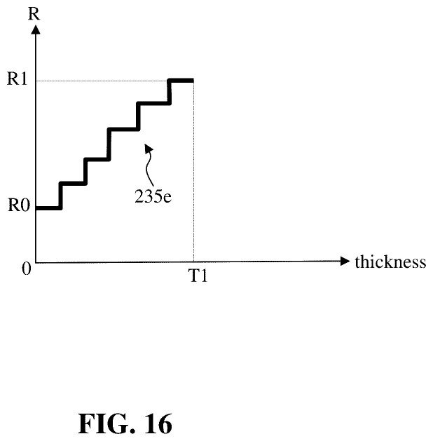

In the above embodiments described with reference to FIGS. 8-10, the ratio R gradually increases as a function of the thickness T1 (or T1′) from the bottom surface 234s1 towards the top surface 234s2. In other embodiments described with reference to FIGS. 11-13 and FIGS. 14-16, the ratio R may increase in a stepwise manner, as represented by the curve 235d shown in FIG. 13 and the curve 235e shown in FIG. 16.

For example, with reference to FIG. 11, the aluminum-containing N-type work function layer 234″ in this embodiment has a first portion 234a″ having a thickness T3 and a second portion 234b″ having a thickness T4. The thickness T3 may be greater than, equal to, or less than the thickness T4. In an embodiment, the thickness T3 is equal to the thickness T4. A ratio R0′ of the concentration (e.g., atomic percentage) of aluminum in the first portion 234a″ of the aluminum-containing N-type work function layer 234″ to a concentration (e.g., atomic percentage) of titanium in the first portion 234a″ of the aluminum-containing N-type work function layer 234″ is uniform (constant), and a ratio R1′ of the concentration (e.g., atomic percentage) of aluminum in the second portion 234b″ of the aluminum-containing N-type work function layer 234″ to a concentration (e.g., atomic percentage) of titanium in the second portion 234b″ of the aluminum-containing N-type work function layer 234″ is also uniform (constant), and the ratio R1′ is greater than the ratio R0′. The thickness relationship between the thickness T0 and the thickness T1 has been described with reference to FIG. 8, and repeated description is omitted for reason of simplicity. In an embodiment, for similar reasons described above, the ratio R0′ is in a range between about 0.4 and about 0.6, and the ratio R1′ is constant and in a range between about 0.6 and about 0.8.

With reference to FIG. 12, the thickness T1 of the aluminum-containing N-type work function layer 234″ is reduced to the thickness T1′. For ease of description, the aluminum-containing N-type work function layer 234′″ having the reduced thickness T1′ is referred to as the aluminum-containing N-type work function layer 234′″. In this embodiment, the aluminum-containing N-type work function layer 234′″ has a first portion 234a′″ and a second portion 234b′″. Compared with the aluminum-containing N-type work function layer 234″ that has the ratio R in the range between about 0.4 and about 0.8, the ratio R of the aluminum-containing N-type work function layer 234′″ may be increased. More specifically, in an embodiment, the ratio R in the aluminum-containing N-type work function layer 234′″ is in a range between about 0.5 and about 1. If the ratio R is less than 0.5, the threshold voltage Vt of the device may not be efficiently reduced, leading to a higher power consumption; and if the ratio R is greater than 1, too many aluminum atoms may diffuse into the gate dielectric layer 232 and the channel layers 208, leading to device performance degradation. The ratio R profile of the aluminum-containing N-type work function layer 234′″ may be similar in shape to the ratio R profile of the aluminum-containing N-type work function layer 234″ represented by FIG. 11, and repeated description may be omitted. In an embodiment, the ratio R in the first portion 234a′″ may be in a range between about 0.5 and about 0.75 and is greater than that of the first portion 234a″ in FIG. 11, and the ratio R in the second portion 234b′″ may be in a range between about 0.75 and about 1 and is greater than the ratio R in the first portion 234a″ and the ratio R in the second portion 234b″ in FIG. 11.

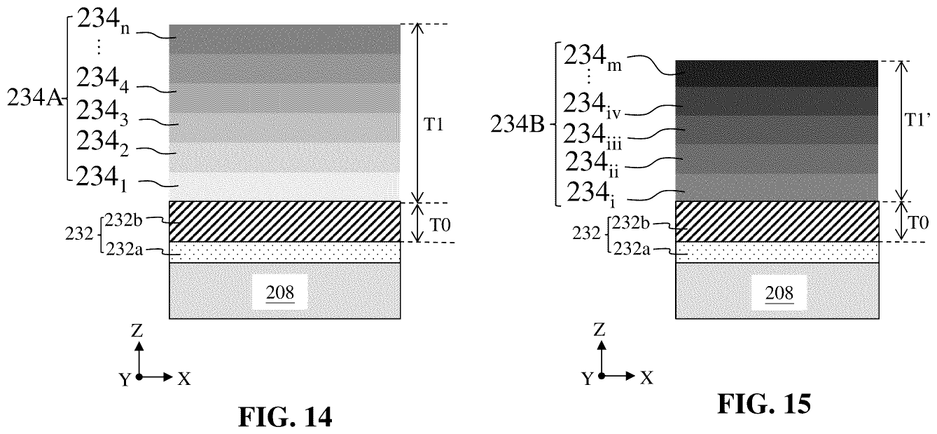

In the above embodiments described with reference to FIGS. 11-13, the aluminum-containing N-type work function layer 234″ or 234′″ each has two sublayers. In other embodiments, with reference to FIGS. 14-15, the aluminum-containing N-type work function layer 234 may have other numbers of multiple sublayers. With reference to FIG. 14, the aluminum-containing N-type work function layer 234 in this embodiment (hereinafter referred to as “the aluminum-containing N-type work function layer 234A”) has sublayers 234₁, 234₂, . . . 234ₙ, where n is an integer and is greater than 2. Each of the sublayers 234₁, 234₂, . . . 234ₙ has a corresponding uniform (constant) ratio R, and the ratio R of the sublayer formed at a higher level is higher than the ratio R of the sublayer formed at a lower level. For example, the sublayer 234₂ is formed above the sublayer 234₁ and under the sublayer 234₃, the ratio R of the sublayer 234₂ is greater than the ratio R (e.g., R0) of the sublayer 234₁ and is less than the ratio R of the sublayer 234₃. The topmost sublayer 234, has the highest ratio R (e.g., R1) among all the sublayers 234₁, 234₂, . . . 234ₙ. In an embodiment, the ratio R of the aluminum-containing N-type work function layer 234A is in a range between about 0.4 and about 0.8. Each of the sublayers 234₁, 234₂, . . . 234ₙ may have a same thickness or may have different thicknesses. In an embodiment, each of the sublayers 234₁, 234₂, . . . 234ₙ has the same thickness. The thickness relationship between the thickness T0 and the thickness T1 has been described with reference to FIG. 8, and repeated description is omitted for reason of simplicity.

With reference to FIG. 15, the thickness T1 of the aluminum-containing N-type work function layer 234A is reduced to the thickness T1′. For ease of description, the aluminum-containing N-type work function layer 234A having the reduced thickness T1′ is referred to as the aluminum-containing N-type work function layer 234B. The aluminum-containing N-type work function layer 234B has multiple sublayers 234ᵢ, 234ᵢᵢ, . . . 234ₘ, where m is an integer and is greater than 2. Each of the sublayers 234ᵢ, 234ᵢᵢ, . . . 234ₘ has a corresponding uniform (constant) ratio, and the ratio R of the sublayer formed at a higher level is higher than the ratio R of the sublayer formed at a lower level. For example, the sublayer 234ᵢᵢ is formed above the sublayer 234ᵢ and under the sublayer 234ᵢᵢᵢ, the ratio R of the sublayer 234ᵢᵢ is greater than the ratio R (e.g., R0) of the sublayer 234ᵢ and is less than the ratio R of the sublayer 234ᵢᵢᵢ. The topmost sublayer 234ₘ has the highest ratio R among all the multiple sublayers 234ᵢ, 234ᵢᵢ, . . . 234ₘ. Each of the sublayers 234ᵢ, 234ᵢᵢ, . . . 234ₘ may have a same thickness or may have different thicknesses. In an embodiment, each of the sublayers 234ᵢ, 234ᵢᵢ, . . . 234ₘ has the same thickness. The thickness relationship between the thickness T0 and the thickness T1′ has been described with reference to FIGS. 8-9, and repeated description is omitted for reason of simplicity. In an embodiment, the ratio R profile of the aluminum-containing N-type work function layer 234B may be in a range between about 0.5 and about 1. The ratio R profile of the aluminum-containing N-type work function layer 234B may be similar in shape to the ratio R profile of the aluminum-containing N-type work function layer 234A represented by FIG. 15, and repeated description may be omitted.

The concentration of aluminum (and the ratio R) in the aluminum-containing N-type work function layer 234 may have other suitable profiles. For example, a lower portion of the aluminum-containing N-type work function layer 234 may have a gradient aluminum concentration profile, and an upper portion of the aluminum-containing N-type work function layer 234B may have a stepwise aluminum concentration profile or a uniform aluminum concentration profile. For another example, a lower portion of the aluminum-containing N-type work function layer 234 may have a stepwise aluminum concentration profile, and an upper portion of the aluminum-containing N-type work function layer 234B may have a gradient aluminum concentration profile.

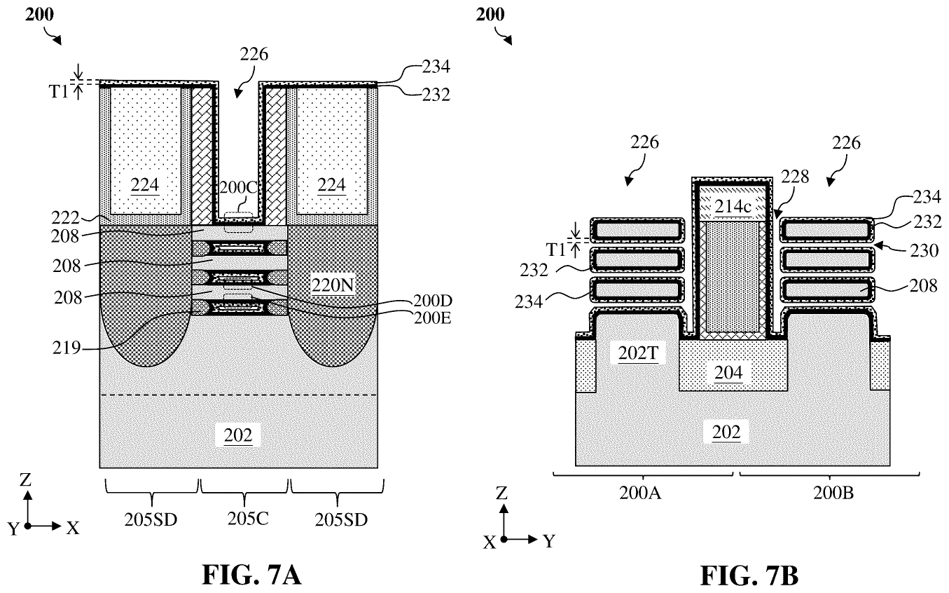

In the above embodiments, the enlarged view of the portion 200C of the structure 200 is described. It is understood that the ratio R profile and the aluminum concentration profile may be applicable to other portions (e.g., 200D, 200E shown in FIG. 7A) of the aluminum-containing N-type work function layer 234 in the structure 200. It is noted that, for embodiments in which the structure 200 will be fabricated to form GAA transistors, a portion of the aluminum-containing N-type work function layer 234 is disposed under the channel layer 208 and the gate dielectric layer 232, as represented by the portion 200E, and a part (e.g., an upper part) of the portion of the aluminum-containing N-type work function layer 234 disposed under the channel layer 208 that is closer to the gate dielectric layer 232 has a lower aluminum concentration, and a part (e.g., a lower part) of the portion of the aluminum-containing N-type work function layer 234 is disposed under the channel layer 208 that is further away from the gate dielectric layer 232 has a higher aluminum concentration.

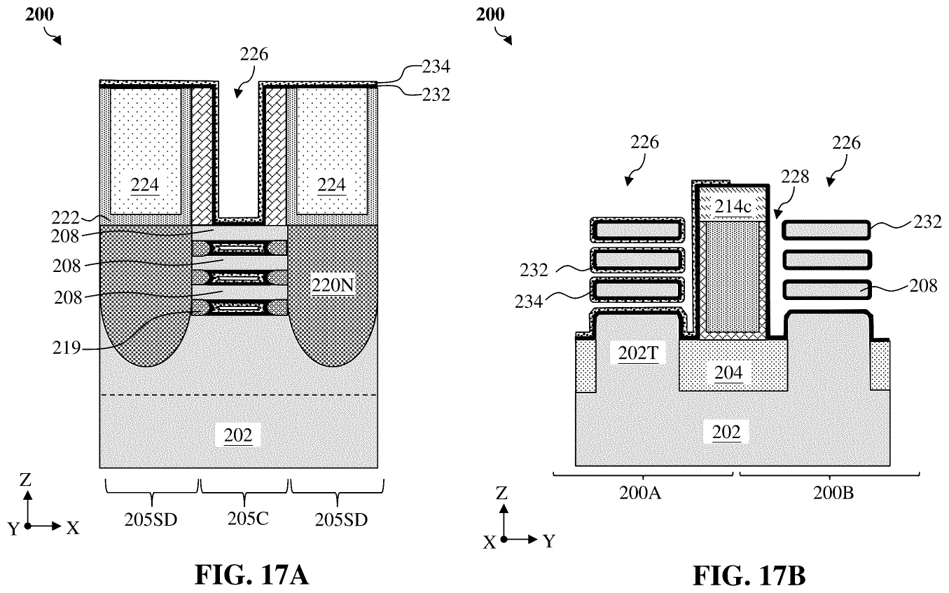

Referring to FIGS. 1 and 17A-17B, method 100 includes a block 114 where a portion of the aluminum-containing N-type work function layer 234 formed in the second device region 200B is removed. In the present embodiments, to substantially prevent aluminum from being diffused in the second device region 200B associated with the aluminum-containing N-type work function layer 234, the portion of the aluminum-containing N-type work function layer 234 formed in the second device region 200B is removed. In an example process, a patterned mask layer (not shown) is formed over the structure 200 to cover the portion of the aluminum-containing N-type work function layer 234 in the first device region 200A, and the portion of the aluminum-containing N-type work function layer 234 formed in the second device region 200A are not covered by the patterned mask layer. The patterned mask layer may include a patterned bottom antireflective coating (BARC) layer, a patterned photoresist layer, a patterned hard mask layer, or combinations thereof. While using the patterned mask layer as an etch mask, an etching process is performed to selectively etch away the portion of the aluminum-containing N-type work function layer 234 in the second device region 200B. The etching process may be a dry etch process, a wet etch process, or a suitable etch process. After the portion of the aluminum-containing N-type work function layer 234 is selectively removed from the second device region 200B, the patterned mask layer may be selectively removed using a suitable etching process.

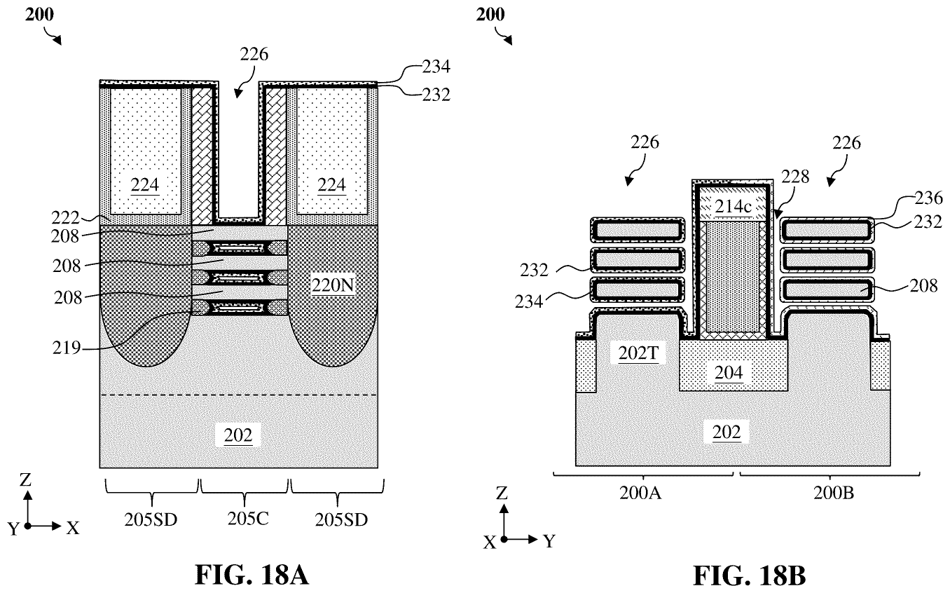

Referring to FIGS. 1 and 18A-18B, method 100 includes a block 116 where a P-type work function layer 236 is formed in the second device region 200B. In some embodiments, the P-type work function layer 236 may include TiN, TaN, Ru, Mo, WN, ZrSi₂, MoSi₂, TaSi₂, NiSi₂, WCN, other p-type work function material, or combinations thereof. In an embodiment, the TiN-based P-type work function layer 236 may also be formed in the first device region 200A and over the aluminum-containing N-type work function layer 234 to reduce aluminum in the aluminum-containing N-type work function layer 234 from being diffused into a metal fill layer formed over the aluminum-containing N-type work function layer 234.

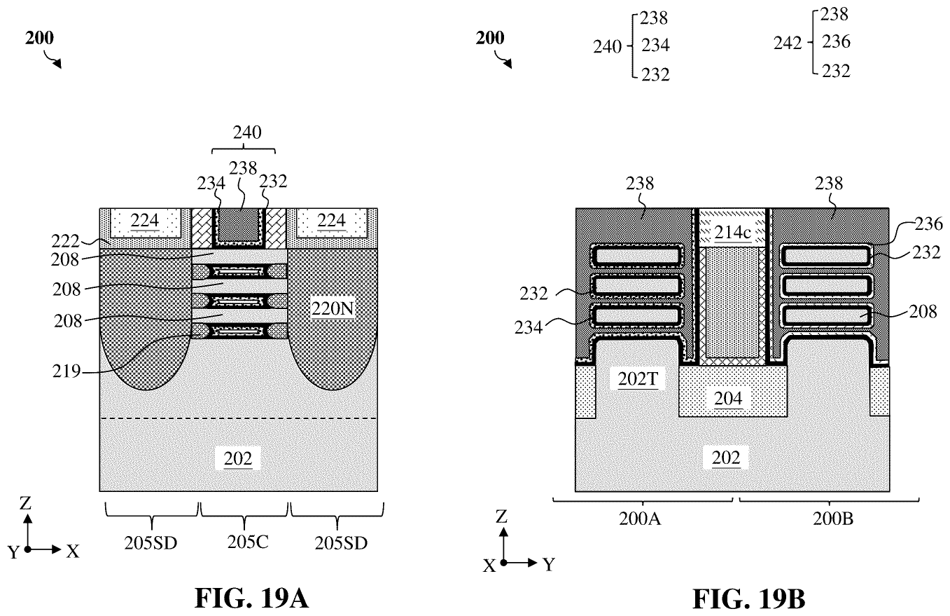

Referring to FIGS. 1 and 19A-19B, method 100 includes a block 118 where one or more conductive layers 238 are formed over the substrate to finish the fabrication of a functional gate stack. In some embodiments of the present disclosure, the one or more conductive layers 238 for devices in the first device region 200A and the second device region 200B may be formed simultaneously or in any sequential order. In an embodiment, the one or more conductive layers 238 may include a metal fill layer such as tungsten (W). In various embodiments, a planarization process (e.g., chemical mechanical polishing (CMP) process) may be performed to remove excessive portions of the materials over the ILD layer, thereby finalizing the structure of gate stack 240 or gate stack 242. In an embodiment, the planarization process stops until the top surface of the helmet layer 214c is exposed.

Referring to FIG. 1, method 100 includes a block 120 where further process are performed. Such further processes may include forming a silicide layer (not depicted) over the source/drain features 220 and a multi-layer interconnect (MLI) structure (not depicted) over the structure 200. The MLI may include various interconnect features, such as vias and conductive lines, source/drain contacts, gate contacts, disposed in dielectric layers, such as etch-stop layers and ILD layers (such as ILD layer 224). In some embodiments, the vias are vertical interconnect features configured to interconnect device-level contacts, such as source/drain contacts formed over the source/drain features 220 and gate contacts (not depicted) formed over the gate stacks 240 and 242.

Although not intended to be limiting, one or more embodiments of the present disclosure provide many benefits to semiconductor devices and the formation thereof. In some embodiments, the present disclosure provides methods for forming N-type transistors with improved performance (e.g., reduced gate leakage current, enhanced carrier mobility) by providing an aluminum-containing work function layer having a non-uniform aluminum concentration from bottom to top. In some embodiments, without adversely affecting the threshold voltages of the N-type transistors, thickness of the aluminum-containing work function layer may be reduced to alleviate gap fill difficulty. Reducing the threshold voltages may also contribute to a decreased threshold voltage variation among different N-type transistors (e.g., pull-down transistors and pass gate transistors in a static random-access memory (SRAM) cell), thereby reducing power consumption and minimum operating voltage Vccmin of the SRAM cell, for example.

The present disclosure provides for many different embodiments. Semiconductor structures and methods of fabrication thereof are disclosed herein. In one exemplary aspect, the present disclosure is directed to a method. The method includes forming a dielectric layer over a portion of a substrate, forming an aluminum-containing work function layer over the dielectric layer, and forming a metal layer over the aluminum-containing work function layer. A concentration of aluminum in a first portion of the aluminum-containing work function layer is different than the concentration of aluminum in a second portion of the aluminum-containing work function layer.

In some embodiments, a ratio of the concentration of aluminum in the aluminum-containing work function layer to a total concentration of other elements in the aluminum-containing work function layer may have a graded profile that gradually increases with the thickness within the aluminum-containing work function layer. In some embodiments, a ratio of the concentration of aluminum in the aluminum-containing work function layer to a total concentration of other elements in the aluminum-containing work function layer may have a stepwise profile. In some embodiments, the aluminum-containing work function layer may have a first sublayer and a second sublayer over the first sublayer, and a first ratio of a concentration of aluminum in the first sublayer to a total concentration of other elements in the first sublayer may be constant and lower than a second ratio of a concentration of aluminum in the second sublayer to a total concentration of other elements in the second sublayer. In some embodiments, the first ratio may be constant and in a range between about 0.4 and about 0.6. In some embodiments, the second ratio may be constant and in a range between about 0.6 and about 0.8. In some embodiments, a thickness of the first sublayer may be equal to a thickness of the second sublayer. In some embodiments, the aluminum-containing work function layer may be an N-type work function layer and comprises TiAl, TiAlC, TaAl, or TiAlN. In some embodiments, the aluminum-containing work function layer may be formed of TiAl, and a ratio of the concentration of aluminum in the aluminum-containing work function layer and a concentration of titanium in the aluminum-containing work function layer may be in a range between about 0.4 and about 1. In some embodiments, the forming of the aluminum-containing work function layer may include performing an atomic layer deposition (ALD) process with a first precursor and a second precursor and changing a flow rate ratio between the first precursor and the second precursor as the aluminum-containing work function layer is deposited during the ALD process.

In another exemplary aspect, the present disclosure is directed to a method. The method includes forming a plurality of nanostructures over a substrate, forming source/drain features coupled to the plurality of nanostructures, and forming a gate structure wrapping around and over each nanostructure of the plurality of nanostructures. The gate structure comprises an aluminum-containing work function layer having a bottom portion over the plurality of nanostructures and a top portion over the bottom portion, and a concentration of aluminum in the top portion is higher than a concentration of aluminum in the bottom portion.

In some embodiments, a ratio of the concentration of aluminum in the bottom portion to a total concentration of other elements in the bottom portion may include a gradient profile. In some embodiments, a ratio of the concentration of aluminum in the top portion to a total concentration of other elements in the top portion may include a gradient profile. In some embodiments, a ratio of a concentration of aluminum in the aluminum-containing work function layer to a total concentration of other elements in the aluminum-containing work function layer may increase in a stepwise manner from a bottom surface of the bottom portion towards a top surface of the top portion. In some embodiments, the aluminum-containing work function layer comprises TiAl, and a ratio of a concentration of aluminum in the aluminum-containing work function layer to a concentration of titanium in the aluminum-containing work function layer may be in a range of between about 0.4 and about 1.

In yet another exemplary aspect, the present disclosure is directed to a semiconductor device. The semiconductor device includes a substrate, a dielectric layer over a portion of the substrate, an aluminum-containing work function layer disposed over the dielectric layer, wherein, within the aluminum-containing work function layer, a concentration of aluminum increases from bottom to top, and a conductive layer disposed over the aluminum-containing work function layer.

In some embodiments, the semiconductor device may also include a plurality of nanostructures over the substrate. The dielectric layer, the aluminum-containing work function layer, and the conductive layer wrap around and are disposed over the plurality of nanostructures. In some embodiments, the aluminum-containing work function layer may include an N-type work function layer and comprises TiAl, TiAlC, TaAl, or TiAlN. In some embodiments, a ratio of the concentration of aluminum to a total concentration of other elements in the aluminum-containing work function layer may be in a range between about 0.4 and about 1. In some embodiments, the ratio may increase in a stepwise manner.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure. For example, by implementing different thicknesses for the bit-line conductor and word line conductor, one can achieve different resistances for the conductors. However, other techniques to vary the resistances of the metal conductors may also be utilized as well.

What is claimed is:

1. A method, comprising:
forming a dielectric layer over a portion of a substrate;
forming an aluminum-containing work function layer over the dielectric layer, wherein, a concentration of aluminum in a first portion of the aluminum-containing work function layer is different than the concentration of aluminum in a second portion of the aluminum-containing work function layer; and
forming a metal layer over the aluminum-containing work function layer.

2. The method of claim 1, wherein a ratio of the concentration of aluminum in the aluminum-containing work function layer to a total concentration of other elements in the aluminum-containing work function layer has a graded profile that gradually increases.

3. The method of claim 1, wherein a ratio of the concentration of aluminum in the aluminum-containing work function layer to a total concentration of other elements in the aluminum-containing work function layer has a stepwise profile.

4. The method of claim 3, wherein the aluminum-containing work function layer comprises a first sublayer and a second sublayer over the first sublayer, and a first ratio of a concentration of aluminum in the first sublayer to a total concentration of other elements in the first sublayer is constant and lower than a second ratio of a concentration of aluminum in the second sublayer to a total concentration of other elements in the second sublayer.

5. The method of claim 4, wherein the first ratio is constant and in a range between about 0.4 and about 0.6.

6. The method of claim 4, wherein the second ratio is constant and in a range between about 0.6 and about 0.8.

7. The method of claim 4, wherein a thickness of the first sublayer is equal to a thickness of the second sublayer.

8. The method of claim 1, wherein the aluminum-containing work function layer is an N-type work function layer and comprises TiAl, TiAlC, TaAl, or TiAlN.

9. The method of claim 8, wherein the aluminum-containing work function layer is formed of TiAl, and a ratio of the concentration of aluminum in the aluminum-containing work function layer and a concentration of titanium in the aluminum-containing work function layer is in a range between about 0.4 and about 1.

10. The method of claim 1, wherein the forming of the aluminum-containing work function layer comprises performing an atomic layer deposition (ALD) process with a first precursor and a second precursor and changing a flow rate ratio between the first precursor and the second precursor as the aluminum-containing work function layer is deposited during the ALD process.

11. A method, comprising:
forming a plurality of nanostructures over a substrate;
forming source/drain features coupled to the plurality of nanostructures; and
forming a gate structure wrapping around and over each nanostructure of the plurality of nanostructures,
wherein the gate structure comprises an aluminum-containing work function layer having a bottom portion over the plurality of nanostructures and a top portion over the bottom portion, and a concentration of aluminum in the top portion is higher than a concentration of aluminum in the bottom portion.

12. The method of claim 11, wherein a ratio of the concentration of aluminum in the bottom portion to a total concentration of other elements in the bottom portion has a gradient profile.

13. The method of claim 11, wherein a ratio of the concentration of aluminum in the top portion to a total concentration of other elements in the top portion has a gradient profile.

14. The method of claim 11, wherein a ratio of a concentration of aluminum in the aluminum-containing work function layer to a total concentration of other elements in the aluminum-containing work function layer increases in a stepwise manner from a bottom surface of the bottom portion towards a top surface of the top portion.

15. The method of claim 11, wherein the aluminum-containing work function layer comprises TiAl, and a ratio of a concentration of aluminum in the aluminum-containing work function layer to a concentration of titanium in the aluminum-containing work function layer is in a range of between about 0.4 and about 1.

16. A semiconductor device, comprising:
a substrate;
a dielectric layer over a portion of the substrate;
an aluminum-containing work function layer disposed over the dielectric layer, wherein, within the aluminum-containing work function layer, a concentration of aluminum increases from bottom to top; and
a conductive layer disposed over the aluminum-containing work function layer.

17. The semiconductor device of claim 16, further comprising:
a plurality of nanostructures over the substrate,
wherein the dielectric layer, the aluminum-containing work function layer, and the conductive layer wrap around and are disposed over the plurality of nanostructures.

18. The semiconductor device of claim 16, wherein the aluminum-containing work function layer is an N-type work function layer and comprises TiAl, TiAlC, TaAl, or TiAlN.

19. The semiconductor device of claim 16, wherein a ratio of the concentration of aluminum to a total concentration of other elements in the aluminum-containing work function layer is in a range between about 0.4 and about 1.

20. The semiconductor device of claim 19, wherein the ratio increases in a stepwise manner.
